(19) United States
(12) Patent Application Publication
(10) Pub. No.: US 2020/0181759 A1
(43) Pub. Date: Jun. 11, 2020

(54) VAPOR DEPOSITION CRUCIBLE

(71) Applicant: Shenzhen China Star Optoelectronics Technology CO., Ltd, Shenzhen Guangdong (CN)

(72) Inventor: Youyuan KUANG, Shenzhen Guangdong (CN)

(73) Assignee: Shenzhen China Star Optoelectronics Technology Co., Ltd, Shenzhen Guangdong (CN)

(21) Appl. No.: 16/340,386

(22) PCT Filed: Dec. 18, 2018
(86) PCT No.: PCT/CN2018/121851

§ 371 Date: Apr. 9, 2019

(30) Foreign Application Priority Data
Dec. 5, 2018 (CN) 201811482603.4

(51) Int. Cl. C23C 14/24; H01L 51/56; H01L 51/00

(52) U.S. Cl. CPC C23C 14/243; H01L 51/001; H01L 51/56

(57) ABSTRACT

A vapor deposition crucible is provided and includes a crucible body and a heat conduction device disposed in the crucible body. The crucible body includes a crucible base and a sidewall connected to the crucible base. The heat conduction device is connected securely to the sidewall, and the heat conduction device is honeycomb-shaped and includes a plurality of channels arranged abreast, extending along an axial direction of the crucible body and configured to accommodate a vapor deposition material. In comparison to the prior art, heat of the vapor deposition material in the channels has a short lateral conduction distance, and the heat received by the vapor deposition material is from the heat conduction device with an excellent heat conductivity such that the vapor deposition material can receive heat sufficiently in the channels, which increases stability of vapor deposition velocity and further improves quality of the OLED display panel.

### FIELD OF INVENTION

The present invention relates to a field of display technologies, especially to a vapor deposition crucible.

### BACKGROUND OF INVENTION

An organic light emitting diode (OLED) display is a very promising flat panel displaying technology. The OLED display has an excellent display performance especially including self-illumination, simple structure, ultra-thinness, fast response times, wide viewing angles, low power consumption, and flexible display and other characteristics, and is known as “dream display.” Furthermore, production equipment investment of the OLED display is much less than thin film transistor liquid crystal display (TFT-LCD) so the OLED display are favored by major display manufacturers and has become a main product of the third generation display device in the field. At present, the OLED display has been on the eve of mass production. With the further research, new technologies continue to emerge, OLED display devices will have a breakthrough development.

There are two manufacturing processes for a thin film of OLED organic material. Regarding a polymer OLED material, a solution film forming process is adopted, and such process is currently in an experimental research stage. Regarding a small molecule OLED material, a vacuum thermal vapor deposition film forming processes is generally adopted, and such process is utilized by most factories of flat panel displaying industries. The vacuum thermal vapor deposition technology is heated under a vacuum environment of 5×10⁻⁵ Pa or lower to make an organic small molecule material sublimate or evaporate into a vapor state. The high-speed moving gaseous molecules reach the glass substrate and deposit and solidify on the substrate, and then change back to the solid film of the OLED material.

In a vapor deposition process, the device used to generate vapor is called evaporation source, and a point vaporization source is heated by a cylindrical crucible with an integral heating filament for heating, as shown in FIG. 1, when vapor deposition is implemented in a vacuum vapor deposition chamber, the OLED material is disposed in a crucible 10, a heat coil 20 is disposed around an outer sidewall of the crucible 10 to heat the OLED material in the crucible 10, when it is heated to reach a temperature for vapor deposition, the OLED material is evaporated, vaporization molecules is ejected out from an outlet hole 35 of the crucible cover 30 and is deposited on the substrate to form a solid thin film. Inappropriate temperature control will lead to a lower temperature of the crucible cover 30 to cause material of the vaporization molecules to accumulate and grow up on the crucible cover 30, which results in blockage of the outlet hole 35 of the crucible. For the OLED organic material, overheating will lead to pyrolysis of the material such that the material cannot be utilized.

Due to the above limitation to the heating method, during heating the crucible 10, not only vertical temperature difference exists from top to bottom, but also lateral temperature difference occurs from left side to right side. The vertical temperature difference will lead to a lower temperature of a base of the crucible 10. When vaporization molecules of the material pass through a top of the crucible 10, the temperature of the crucible 10 exceeds a pyrolysis temperature of the material such that the device has lowered performance. In order to prevent this from happening, the material at the base of the crucible 10 is usually wasted. Furthermore, the OLED organic material is a hot non-thermal conductor, which has low heat transfer efficiency, and a long propagation path affects heat transfer efficiency. Material (non-thermal conductor) at the base of the crucible 10 bottom, the heat transfer loss is large, as shown In FIG. 2, which often leads that the material at a center of the base of the crucible 10 is not heated enough, cannot be completely vapor deposited out and is left in crucible 10.

### SUMMARY OF INVENTION

An objective of the present invention is to provide a vapor deposition crucible that can effectively reduce lateral temperature difference of an inside vapor deposition material, lower risk of pyrolysis of material, increases stability of vapor deposition velocity, and further improves quality of the OLED display panel.

To achieve the above objective, the present invention provides a vapor deposition crucible, comprising a crucible body and a heat conduction device disposed in an inside of the crucible body;

the crucible body comprising a crucible base and a sidewall connected to the crucible base; and

the heat conduction device connected securely on the sidewall, and the heat conduction device being honeycomb-shaped and comprising a plurality of channels arranged abreast, extending along an axial direction of the crucible body and configured to accommodate a vapor deposition material.

The heat conduction device includes at least one hollow structure extending through the channels.

The at least one hollow structure serves a buffer layer configured to accommodate the vapor deposition material and makes the channels communicate with one another.

The channels have a quantity of at least two.

A material of the crucible body is silver, titanium, aluminum or stainless steel.

A material of the heat conduction device is silver, titanium, aluminum or stainless steel.

A material of the heat conduction device is silver, titanium, aluminum or stainless steel.

A material of the heat conduction device is the same as a material of the crucible body.

The crucible body and the heat conduction device are made by mechanical machining operation to a same metal rod by cutting away a part of the metal rod therefrom.

An inner surface of the sidewall is oblique relative to the crucible base.

The heat conduction device includes an outer surface completely fitting the inner surface of the sidewall, and the heat conduction device is engaged with and connected to the inner surface of the sidewall by gravity itself.

The vapor deposition crucible further includes a top lid portion disposed on the crucible body, and an outlet hole is defined in a center of the top lid portion.

The vapor deposition crucible further includes a heat coil disposed around an outside of the crucible body and configured to heat the vapor deposition material.

Advantages of the present invention: the present invention provides a vapor deposition crucible, comprising a crucible body and a heat conduction device disposed in an inside of the crucible body, the crucible body comprising a crucible base and a sidewall connected to the crucible base; and the heat conduction device connected securely on the sidewall, and the heat conduction device being honeycomb-shaped and comprising a plurality of channels arranged abreast, extending along an axial direction of the crucible body and configured to accommodate a vapor deposition material. In comparison to the prior art, heat of the vapor deposition material in the channels has a short lateral conduction distance, and the heat received by the vapor deposition material is from the heat conduction device with an excellent heat conductivity such that the vapor deposition material can receive heat sufficiently in the channels, which greatly reduces the lateral conduction path of the eat in the non-thermal conductor, drastically decreases the lateral temperature difference in the inside vapor deposition material, increases utilization rate of the vapor deposition material, lowers risk of pyrolysis of material, increases stability of vapor deposition velocity, and further improves quality of the OLED display panel.

In order to further understand the features and technical contents of the present invention, the following detailed description and drawings of the present invention are referred to. However, the drawings are only provided for reference and explanation, and are not intended to limit the present invention.

### DESCRIPTION OF DRAWINGS

The technical solutions and other beneficial effects of the present invention will be apparent from the detailed description of the specific embodiment of the present invention with reference to the accompanying drawings.

In the drawings,

FIG. 1 is a schematic structural view of a conventional vapor deposition crucible;

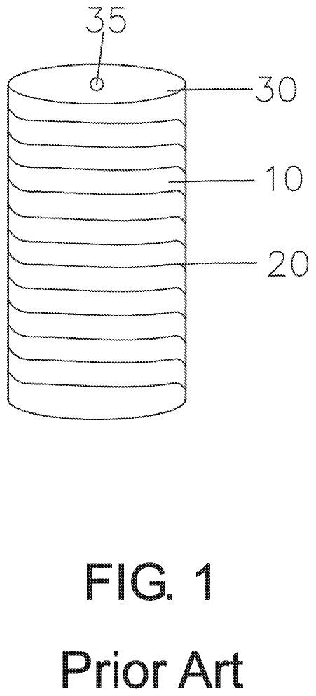

FIG. 2 is a schematic view of a status of remaining material of a vapor deposition material in a vapor deposition crucible of the conventional vapor deposition process;

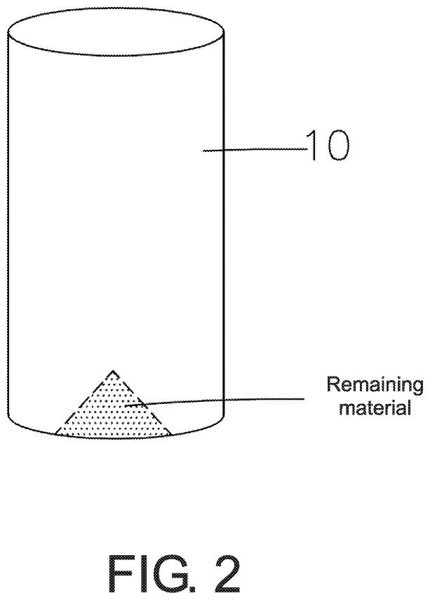

FIG. 3 is a cross sectional structural view of a first embodiment of a vapor deposition crucible of the present invention; and

FIG. 4 is a cross sectional structural view of a second embodiment of the vapor deposition crucible of the present invention.

### DETAILED DESCRIPTION OF PREFERRED EMBODIMENTS

In order to further explain the technical means and effects of the present invention, the following describes the preferred embodiments of the present invention and its accompanying drawings.

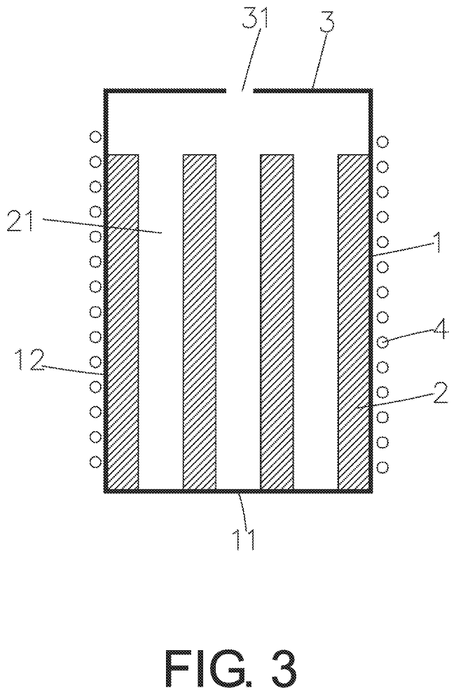

With reference to FIG. 3, FIG. 3 is a cross sectional structural view of a first embodiment of a vapor deposition crucible of the present invention. The present embodiment includes a crucible body 1, a heat conduction device 2 disposed in an inside of the crucible body 1, a top lid portion 3 is disposed above the crucible body 1, and a heat coil 4 disposed around an outside of the crucible body 1 and is configured to heat the vapor deposition material.

The crucible body 1 includes a crucible base 11 and a sidewall 12 connected to the crucible base 11. An outlet hole 31 is defined in a center of the top lid portion 3.

The heat conduction device 2 is connected securely to the sidewall 12, the heat conduction device 2 is honeycomb-shaped and includes a plurality of channels 21 arranged abreast, extending along an axial direction of the crucible body 1 and configured to accommodate a vapor deposition material.

When vapor deposition is implemented, heat generated by the heat coil 4 is conducted from an outside of the sidewall 12 to the heat conduction device 2 connected to the sidewall 12, and then is further transferred to the vapor deposition material in the channels 2 such that a lateral conduction path in a non-thermal conductor along which the heat travels is decreased, and the lateral temperature difference in the vapor deposition material is reduced.

Specifically, a material of the heat conduction device 2 is the same as a material of the crucible body 1, both of the materials are thermal conductor materials including excellent thermal conductivity.

Furthermore, the material of the heat conduction device 2 can be a thermal conductor material such as silver, titanium, aluminum or stainless steel.

Specifically, the crucible body 1 and the heat conduction device 2 are made by mechanical machining operation to a same metal rod by cutting away a part of the metal rod therefrom.

Alternatively, the crucible body 1 and the heat conduction device 2 are made of different metal materials respectively. An inner surface of the sidewall 12 of the crucible body 1 is oblique relative to the crucible base 11. The heat conduction device 2 includes an outer surface completely fitting the inner surface of the sidewall 12. The heat conduction device 2 is engaged with and connected to the inner surface of the sidewall 12 by gravity itself.

Specifically, the channels 21 include a quantity of at least two.

It should be noted that in the above first embodiment, all of the channels 21 in the heat conduction device 2 do not communicate with one another. Therefore, when one of the channels 21 is blocked, a velocity of vapor deposition gas at the outlet hole 31 of the top lid portion 3 suddenly drops, which disadvantages stability of the vapor deposition process. Alternatively, after one of the channels 21 is blocked, as heating continues, the vapor deposition material in the channels 21 is evaporated and expands. When an internal pressure exceeds a predetermined threshold, the vapor deposition gas impacts and opens the blocked channel 21 and inevitably causes a sudden surge of the velocity of the vapor deposition gas at the outlet hole 31, which also disadvantages stability of the vapor deposition process.

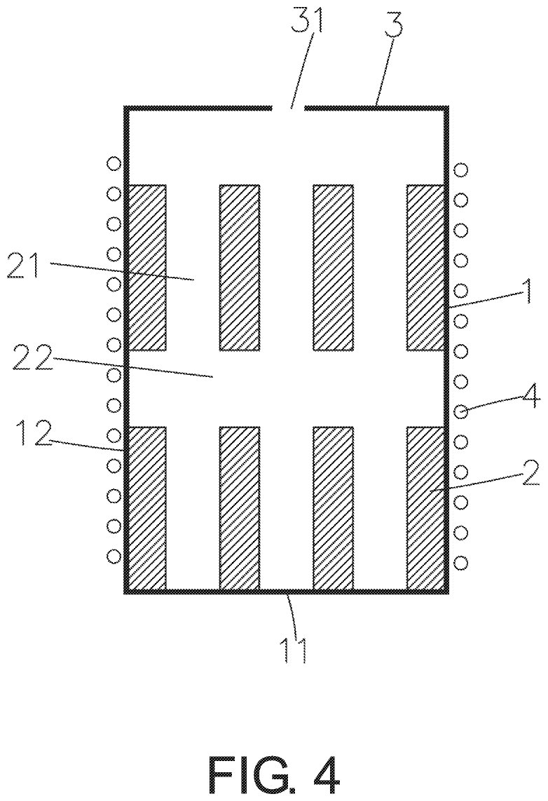

With reference to FIG. 4, FIG. 4 is a cross sectional structural view of a second embodiment of the vapor deposition crucible of the present invention. A difference of the present embodiment from the above first embodiment lies in that the heat conduction device 2 includes at least one hollow structure 22 extending through the channels 21. The hollow structure 22 serves as a buffer layer for accommodating partial vapor deposition material and makes the channels 21 to communicate with one another. Thus, in the vapor deposition process, when one of the channels 21 is blocked, the vapor deposition gas in the hollow structure 22 compensates a velocity loss of the vapor deposition gas of the outlet hole 31 at an uppermost end of the channels 21 due to the blockage, which ensures stability of the velocity of the vapor deposition. Furthermore, as the vapor deposition process continues, the blocked channel 21 is crashed to open, a lower pressure in the hollow structure 22 mixes with the greater pressure released in the channel 21, which ensures stability of the velocity of the vapor deposition gas of the outlet hole 31 at the uppermost end and further ensures stability of the velocity of the vapor deposition. Other features in the present embodiment are the same as those in the first embodiment and will not be described repeatedly.

The vapor deposition crucible of the present invention, heat received by the vapor deposition material is from the heat conduction device 2 with an excellent heat conductivity, such that the vapor deposition material can receive heat sufficiently in the channels 21, and heat of the vapor deposition material in the channels 21 has a short lateral conduction distance, which greatly reduces the lateral conduction path of the eat in the non-thermal conductor, drastically decreases the lateral temperature difference in the inside vapor deposition material, increases utilization rate of the vapor deposition material, lowers risk of pyrolysis of material, increases stability of vapor deposition velocity, and further improves quality of the OLED display panel.

As described above, a vapor deposition crucible provided by the present invention includes a crucible body and a heat conduction device disposed in an inside of the crucible body. The crucible body includes a crucible base and a sidewall connected to the crucible base. The heat conduction device is connected securely to sidewall, and the heat conduction device is honeycomb-shaped and includes a plurality of channels arranged abreast, extending along an axial direction of the crucible body and configured to accommodate a vapor deposition material. In comparison to the prior art, heat of the vapor deposition material in the channels has a short lateral conduction distance, and the heat received by the vapor deposition material is from the heat conduction device with an excellent heat conductivity such that the vapor deposition material can receive heat sufficiently in the channels, which greatly reduces the lateral conduction path of the eat in the non-thermal conductor, drastically decreases the lateral temperature difference in the inside vapor deposition material, increases utilization rate of the vapor deposition material, lowers risk of pyrolysis of material, increases stability of vapor deposition velocity, and further improves quality of the OLED display panel.

As described above, various other changes and modifications can be made by a person of ordinary skill in the art in light of the technical scope and technical concept of the present invention, and all such changes and modifications are to be protected by the present invention. range.

What is claimed is:

1. A vapor deposition crucible, comprising a crucible body and a heat conduction device disposed in an inside of the crucible body;
the crucible body comprising a crucible base and a sidewall connected to the crucible base; and
wherein the heat conduction device is connected securely on the sidewall, and the heat conduction device is honeycomb-shaped and comprises a plurality of channels arranged abreast, extending along an axial direction of the crucible body and configured to accommodate vapor deposition material.

2. The vapor deposition crucible as claimed in claim 1, wherein
the heat conduction device comprises at least one hollow structure extending through the channels; and
the at least one hollow structure serves a buffer layer configured to accommodate the vapor deposition material and make the channels communicate with one another.

3. The vapor deposition crucible as claimed in claim 1, wherein the channels have a quantity of at least two.

4. The vapor deposition crucible as claimed in claim 1, wherein a material of the crucible body is silver, titanium, aluminum, or stainless steel.

5. The vapor deposition crucible as claimed in claim 1, wherein a material of the heat conduction device is silver, titanium, aluminum, or stainless steel.

6. The vapor deposition crucible as claimed in claim 1, wherein a material of the heat conduction device is same as a material of the crucible body.

7. The vapor deposition crucible as claimed in claim 1, wherein the crucible body and the heat conduction device are made by mechanical machining operation to a same metal rod by cutting away a part of the metal rod therefrom.

8. The vapor deposition crucible as claimed in claim 1, wherein
an inner surface of the sidewall is oblique relative to the crucible base; and
the heat conduction device comprises an outer surface completely fitting the inner surface of the sidewall, and the heat conduction device is engaged with and connected to the inner surface of the sidewall by gravity itself.

9. The vapor deposition crucible as claimed in claim 1 further comprising a top lid portion disposed on the crucible body, and an outlet hole is defined in a center of the top lid portion.

10. The vapor deposition crucible as claimed in claim 1 further comprising a heat coil disposed around an outside of the crucible body and configured to heat the vapor deposition material.
